(19) United States
(12) Patent Application Publication
(10) Pub. No.: US 2002/0175312 A1
(43) Pub. Date: Nov. 28, 2002

(54) Thermoelectric materials formed based on chevrel phases

(76) Inventors: Jean-Pierre Fleurial, Duarte, CA (US); G. Jeffrey Snyder, Altadena, CA (US); Alexander Borshchevsky, Santa Monica, CA (US); Thierry Caillat, Pasadena, CA (US)

Correspondence Address: FISH & RICHARDSON, PC, 4350 LA JOLLA VILLAGE DRIVE, SUITE 500, SAN DIEGO, CA, 92122, US

(21) Appl. No.: 09/904,191

(22) Filed: Jul. 11, 2001

Related U.S. Application Data
(60) Provisional application No. 60/217,343, filed on Jul. 11, 2000.

(51) Int. Cl. C01B 19/00; C22C 38/02; H01L 35/22

(52) U.S. Cl. 252/62.3 T; 423/508; 136/238

(57) ABSTRACT

Chevrel phase materials are used as thermoelectric materials. The Chevrel phase materials are formed as units, and the units include voids between the units. Those voids may be filled with filling elements. The filling elements can be large elements such as lead, or smaller elements such as metals. Exemplary metals may include Cu, Ti, and/or Fe. Different Chevrel phase materials are discussed, including Mo based Chevrel phase materials and Re based Chevrel phase materials.

### CROSS REFERENCE TO RELATED APPLICATIONS

The present application claims priority from provisional No. 60/217,343, filed Jul. 11, 2000.

### STATEMENT AS TO FEDERALLY-SPONSORED RESEARCH

The invention described here was made in the performance of work under a NASA 7-1407 contract, and is subject to the provisions of Public Law 96-517 (U.S.C. 202) in which the contractor has elected to retain title.

### BACKGROUND

Thermoelectric generators may operate by converting changes between hot and cold areas into electrical energy, without moving parts. Advantages of thermoelectric generators may include their ability to reliably operate unattended, in many different environments including hostile environments. Moreover, no waste products are produced by thermoelectric operation, making such thermoelectric generators environmentally friendly.

Applications of such generators have been limited by the relatively low efficiency and high cost of the thermoelectric materials.

Moreover, the different known thermoelectric materials operate in a specified temperature range. Other temperature ranges may be desirable.

Efficiency of a thermoelectric material may be measured by the figure of merit ZT, of the material. Increasing the figure of merit of the material may increase the efficiency of the thermoelectric material. Figure of merit of the material ZT is defined as:

ZT=α²T/ρλ,

where α is the Seebeck coefficient, ρ is the electrical resistivity, and λ is the thermal conductivity.

A specific type of thermoelectric generator is called a radioisotope thermoelectric generator or RTG. These generators may be used in space missions and other hostile environments. These devices may have relatively limited efficiency, e.g. around 6 percent.

### SUMMARY

The present application describes special new thermoelectric materials based on materials that have Chevrel phases. In particular, Chevrel phases which include metallic additions are disclosed. The metallic additions may include Cu, Cu Fe, and Ti, or other materials, filling the voids in the Chevrel phase compositions. These materials may include rattling elements within the matrix that may improve the thermoelectric effect.

### BRIEF DESCRIPTION OF THE DRAWINGS

These and other aspects will now be described in detail, with reference to the accompanying drawings, wherein:

FIG. 1 shows a basic of a rhombohedral Chevrel phase structure;

FIG. 2 shows a diagram showing larger sized filling atoms within the voids of the Chevrel phase structure;

FIG. 3 shows smaller filling atoms within the voids of the Chevrel phase structure;

FIG. 4 shows a chart of electrical resistivity vs. inverse temperature for specified metal-filled phases;

FIG. 5 shows the Seebeck coefficient as a function of temperature for these specified metal filled phases;

FIG. 6 shows thermal conductivity vs. temperature for these specified metal filled phases;

FIG. 7 shows the unit cells and clusters of the Re based Chevrel phases.

### DETAILED DESCRIPTIONS

The inventors have recognized, based on study of mechanisms responsible for high phonon scattering rates in these compounds, that materials with additional atoms in their lattice are more likely to possess low lattice thermal conductivity values. Several low thermoelectric conductivity materials have been identified and developed over the years. These materials may include filled skutterudites, and Zn₄Sb₃ materials. The inventors have recognized an additional such material as a Chevrel phase.

Ternary chalcogenides of formula MₓMo₆X₈, where M is Cu, Ag, Ni or Fe, or rare earth, and X is S, Se or Te, are often referred to as Chevrel compounds. These materials have structures which are closely related to those of binary Mo chalcogenides of form Mo₆X₄.

The crystal structure of the Chevrel phase materials may have cavities within the crystal. These voids may vary in size. An embodiment may include a variety of different filling atoms, ranging from large atoms such as Pb to smaller atoms such as Cu within those cavities. These materials, with a Chevrel phase structure, and a filling atom within the crystal portion of the Chevrel phase structure, is referred to as a filled Chevrel phase material

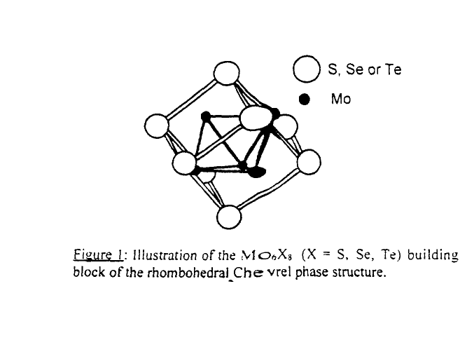

The basic unit of a first material is shown in FIG. 1. This includes an Mo₆ octahedron cluster surrounded by 8 chalcogens (e.g., S, Se or Te) arranged in a distorted cube, or rhombohedron.

Other Chevrel phases, of specified materials, are known. According to the present application, various filled Chevrel phases are used as thermoelectric materials. Specific characteristics and properties of those materials are disclosed.

The present application also discloses using Chevrel phase materials as thermoelectric materials, for example in a thermoelectric circuit producing energy.

A specific Chevrel phase of Mo₆Se₈ is disclosed. This material may have a low a lattice thermal conductivity, which may be necessary to achieve a high thermoelectric figure of merit ZT. The various types of materials are discussed herein, including samples of filled compositions including (Cu, Cu/Fe, Ti) xMo₆Se₈ samples and investigations of their thermoelectric properties.

Selection of the filling elements is disclosed herein in order to control the electrical and thermal properties of these materials. In one embodiment, representing one of the best calculated ZT values, an a-type Cu/Fe filled composition is used with a ZT of 0.6 at 1150 degrees K.

The different Chevrel phases which are used herein include a rhombohedral Chevrel phase. This phase has a stacking of Mo₆X₈ units, and includes channels where additional metal atoms can be inserted. This forms MₓMo₆X₈ compounds, where M can be any of a variety of different atoms such as Ag, Sn Ca, Sr, Pb, Ba, Ni, Co, Fe, Cr, Mn or others. Many of the physical and structural properties of such ternary Chevrel phases depend on the size and electronic configuration of these filling atoms.

The inventors have found that insertion of Fe or Co atoms in the voids efficiently scatters the phonons, resulting in room temperature lattice thermal conductivity values around 10 mw/cmK. This is comparable to state-of-the-art thermoelectric materials including heavily doped semiconductors.

A specific experiment forms single phase, polycrystalline samples of (Cu, Cu/Fe, Ti)ₓMo₆Se₈, by mixing and reacting stoichiometric amounts of Cu, Fe, Ti, Mo and Se powders.

The powders were first mixed in a plastic vial using a mixer. An annealing cycle is carried out, by loading the powder into quartz ampules which are evacuated and sealed. The ampules are heated at 1470 degree Kelvin for two days. Then, the powder is crushed and ground to obtain single phase material. A total of 3 of these annealing cycles is carried out, for two days each.

If desired, the samples may then be analyzed by x-ray diffractometry.

After processing the powders using this annealing operation, the powder may then be hot pressed in graphite dies into dense samples. The hot pressing may occur at a pressure of about 20,000 PSI, at temperatures between 1123 and 1273 degrees Kelvin for about two hours under an argon atmosphere. Each sample may be for example 10 mm long and 6.35 mm in diameter.

Analysis showed that the samples were formed of about 97 percent of a phase corresponding to the Mo₆Se₈ phase, and further characterized for other characteristics as shown in table 1.

TABLE I
Some properties of Cu, Cu/Fe, and Ti filled compositions at 300K

| | Units | Cu₄Mo₆Se₈ | Cu₂FeMo₆Se₈ | TiMo₆Se₈ |
|---|---|---|---|---|
| Microprobe | at % | Cu_{3.1}Mo₆Se₈ | Cu_{1.38}Fe_{0.66}Mo₆Se₈ | Ti_{0.9}Mo₆Se₈ |
| composition | | | | |
| Conductivity type | | p | p | p |
| Electrical resistivity | mΩcm | 0.84 | 1.09 | 6 |
| Seebeck coefficient | μV/K | 14 | 16 | 70 |
| Hall carrier | cm⁻³ | 8.8 × 10²¹ | 9 × 10²¹ | 1.8 × 10²¹ |
| concentration | | | | |
| Hall mobility | cm²/Vs | 0.4 | 3.6 | 0.6 |
| Thermal | mW/cmK | 10 | 10.5 | 10.2 |
| conductivity | | | | |

All of the samples showed p-type conductivity.

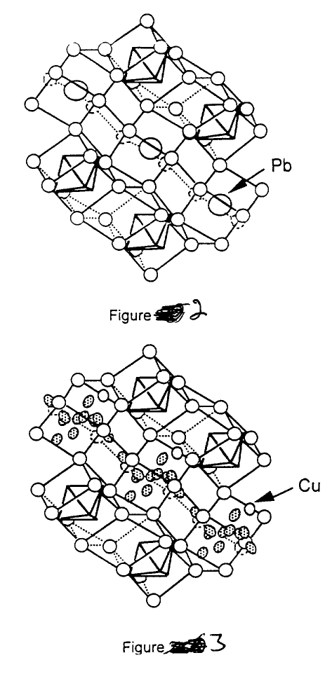

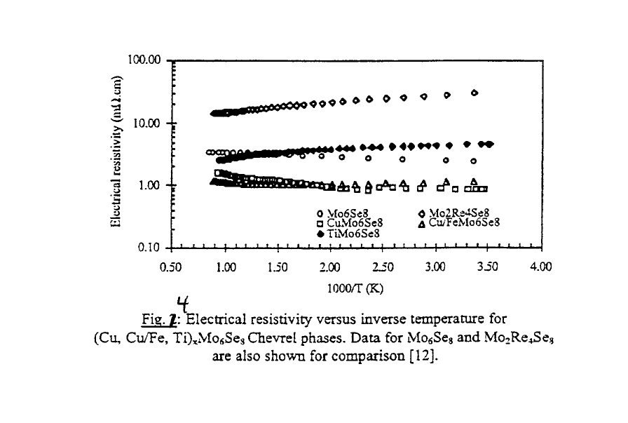

As described above, stacking of Mo₆Se₈ units leaves empty channels where additional metal atoms can be inserted. This is shown in FIGS. 2 and 3. FIG. 2 shows the Chevrel structure shown by a cubic shape formed by 8 chalcogen atoms. Larger atoms such as Pb and La can occupy the largest of the voids, with a fill factor limit corresponding to x of approximately 1. Smaller atoms, such as Cu, Ni or Fe, for example, can be inserted in the smaller holes with irregular shapes in the top edge in channels as shown in FIG. 3. Based on the geometrical factors, these 12 sites cannot be occupied simultaneously, hence leading to a theoretical fill limit of six metal atoms. For smaller atoms, in fact, the upper occupancy limit has been experimentally found to be around x=4.

The number of electrons per Mo atom in the cluster, often referred to as be “cluster-valence-electron count”, or cluster vEC, may be calculated by adding the number of valence electrons of the M atoms to the valence electrons of the Mo atoms, and subtracting the number of electrons required to fill the octets of the chalcogen atoms, and dividing the result by the number of Mo atoms. Chevrel phases are formed for cluster EC numbers between 3.3 and 4.

Band structure calculation results predict an energy gap in the electronic structure for four valence atoms per Mo atom in the cluster. The values of four are obtained in mixed metal cluster compounds such as Mo₂Re₄Se₈ and Mo₄Re₂Se₈. These compounds were found to be semiconductors, thus supporting that an energy gap in the band structure of the Chevrel phase may have significant advantages when its cluster v EC number is around 4, e.g., between 3.3 and 4.7.

Three particularly interesting compositions include Cu₄Mo₆Se₈, Cu₂FeMo₆Se₈, and TiMo₆Se₈. Each of these materials has a calculated the EC of four, and would be expected to be semiconductor materials.

A specifically interesting compound may be Cu₄Mo₆Se₈. This is a pseudo binary compound with a VEC of four. This material was found to be semiconducting. However, only very small amounts of the additional element M, here Sn, can be introduced into the compound. This might be explainable since the cluster VEC is already four, and bands below the gap are already completely filled. This may prevent insertion of additional M atoms.

The Cu compound Cu₂Mo₃Re₃Se₈ also has a cluster VEC of four, and hence has semiconducting properties. This compound might also be particularly attractive, since it will likely scattering both the point defects and void fillers.

Each of the three interesting compounds noted above had a practical degree of filling which was less than the nominal value. This may be due to the difference in covalency in the sulfides, selenides and tellurides. Hence, the formal charge of Se and Te is smaller than the charge for S. Fewer electrons may therefore be needed in the selenides and tellurides to reach of the EC of four, and hence the state that is mostly likely to be the semiconductor.

For the selenides, it is estimated that the formal charge of Se decreases by ⅛ compared to that of sulfur. Therefore, assuming a charge of −2 for sulfur, then three additional electrons may be needed to achieve of the VEC of four for selenides and potentially reach the superconducting state. The filling limit is therefore reached for smaller x, consistent with the results shown in table 1.

Moreover, the high temperature annealing that is carried out, obtains close to a single phase sample, but may also generate defects that block the voids and therefore limit metal atom occupancy.

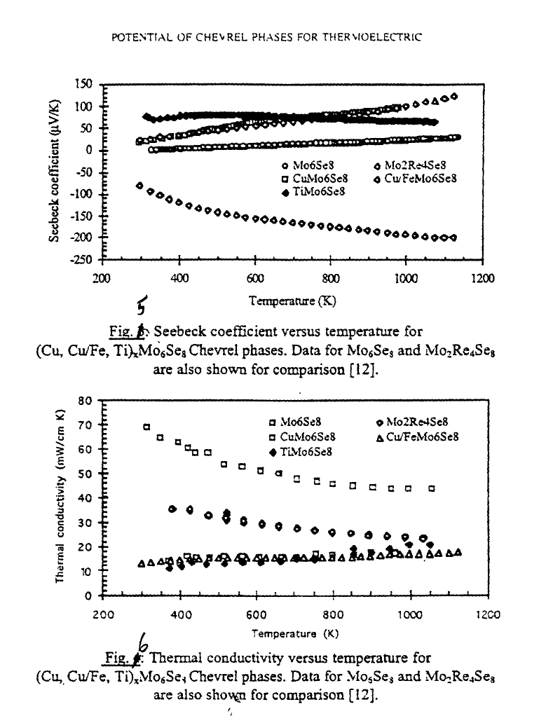

Temperature variations in these materials are shown in FIGS. 4 and 5. The charted values show that Cu and Cu/Fe and filled compositions behave as semi metals, while Ti filled compositions show a semiconductor behavior. The Ti filled compositions may be the first truly semiconducting ternary phase obtained. The shows significant promise with respect to controlling electronic properties of these materials. Moreover, carrier mobility of these materials may be relatively low, resulting in a relatively high electrical resistivity value.

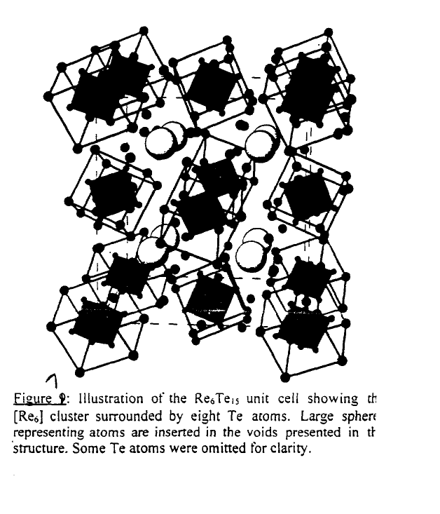

The thermal conductivity data is shown in FIG. 6. Room temperature thermal conductivity for Mo₆Se₈ is about 70 mw/cmK, and the thermal conductivity decreases with increasing temperature, to a minimum value of about 45 mw/cmK, at 1100 degrees Kelvin.

For Mo₂Re₄Se₈, the thermal conductivity may be significantly lower; i.e. with a room temperature conductivity of 40 mw/cmK. The relatively large electrical resistivity values cause a total thermal conductivity to correspond to approximately 98 percent of the lattice contribution. The thermal conductivity varies approximately as the square root of T indicative of phonon scattering by point defects that are introduced by the substitution of Re for Mo atoms. Hence, a decrease in thermal conductivity may be seen for these ternary compositions.

It has been suggested that the crystals with loosely bound atoms may have phonons that are scattered more strongly than electrons/holes. Such an ideal thermoelectric material has been called a phonon/glass/electron/crystal PGEC or material.

The decrease in thermal conductivity may be predominantly attributed to be “rattling” of the Cu, Fe or Ti atoms in the voids of the Chevrel structure. The thermal parameter measures the ability of the ion to rattle inside the cage, and may be a measure of the effectiveness of the voids filler in scattering phonons. Table 2 shows these parameters, and shows that the thermal parameter in the direction perpendicular to the ternary axis for small atoms is about two orders of magnitude larger than those for large atoms such as La or Sn, and for Mo and Se atoms. These thermal parameters also correlate with the low lattice thermal conductivity for composition 1.

TABLE II
Thermal vibration parameters for several atoms in MₓMo₆Se₈
ternary compositions (after [12]).

| | Thermal parameter | Thermal parameter |
|---|---|---|
| Element and | ⊥ ternary axis | // ternary axis |
| filling fraction | (Å²) | (Å²) |
| Cu_{1.0} | 0.869 | ˜0 |
| Ag | 0.144 | 0.004 |
| Sn_{0.8} | 0.052 | 0.085 |
| La_{0.8} | 0.005 | 0.013 |
| Mo | 0.007 | 0.006 |
| Se | 0.014 | 0.011 |

As the table shows, the best calculated ZT values occur for the Cu/Fe and filled compositions with the ZT of points at 1150 degrees K. This value may be comparable to those obtained for Si—Ge alloys in the same temperature range. Moreover, even larger Seebeck coefficients can be obtained for semiconductor ternary compositions such as Ti_{0.9}Mo₆Se₈. Combined with the low lattice thermal conductivity, and potentially tunable electronic properties, these features may be highly advantageous in thermoelectric applications.

Another embodiment describes the cluster compound Re₆Te₁₅. This compound, with 84 atoms per unit cell, belongs to the space group Pbca with a=13.003 Å, b=12.935 Å and c=14.212 Å. The crystal structure presents some similarities with the Chevrel phases and the Re atoms are also arranged in octahedral [Re₆] clusters.

Samples were made. In general the samples were characterized by high Seebeck coefficient values as well as high electrical resistivity values. The heavy atoms constituting the compound as well as the large number of atoms per unit cell may produce low thermal conductivity. It was also found that up to 40% of the Te atoms can be replaced by Se atoms. This offers further possibilities to achieve lower thermal conductivity than for the binary compound Re₆Te₁₅ itself.

Experiment

Single phase polycrystalline samples of Re₆Te₁₅₋ₓSeₓ were prepared by mixing and reacting stoichiometric amounts of rhenium (99.997%), tellurium (99.999%) and selenium (99.999%) powders. The powders were first mixed in a plastic vial using a mixer before being loaded into a quartz ampoule which was evacuated and sealed. The ampoules were then heated at 773K for 10 days with one intermediate crushing. The samples were analyzed by x-ray difractometry (XRD) to check that they were single phase. The powders were then hot-pressed in graphite dies into dense samples that are 10 mm long and 6.35 mm in diameter. The hot-pressing was conducted at a pressure of about 20,000 psi and a temperature of 773 K for about 2 hours under an argon atmosphere. The density of the samples was calculated from the measured weight and dimensions were found to be about 97% of the theoretical density.

The samples were characterized using the same microstructure and measurement techniques described in the experimental section for the Chevrel phases.

The electrical resistivity and the Seebeck coefficient values are reported for Re₆Te₁₅ and Re₆Se₂₂₅Te₁₂₇₅ in FIGS. 6 and 7 respectively. All samples showed p-type conductivity with large Seebeck coefficient values and large electrical resistivity values. The room temperature carrier mobility for Re₆Te₁₅ was 4 cm²V⁻¹S⁻¹ for a carrier concentration of 2×10¹⁸ cm⁻³. The electrical resistivity is high, due to the low carrier mobility. For Re₆Te₁₅, both electrical resistivity and Seebeck coefficients decrease with increasing temperature, as expected for the intrinsic semiconductor. The electrical resistivity varies linearly with temperature at high temperatures. An activation energy of 0.8 eV was calculated.

A different behavior is observed for the Re₆Se_{2.25}Te_{12.75} solid solution. Both Seebeck coefficient and electrical resistivity increase with increasing temperature and only at the highest temperatures of measurements, an onset of intrinsic behavior can be observed. However, the electrical resistivity are also relatively high which is due again to relatively poor carrier mobility in the order of 1-2 cm²V⁻¹S⁴.

At room temperature, the thermal conductivity for Re₆Te₁₅ is about 14 mW/cmK and is comparable to p-type Bi₂Te₃—based allows. The thermal conductivity of Re₆Te₁₅ decreases with increasing temperature following reasonably well 1/T dependence, as expected for phonon-phonon scattering.

For the Re₆Se_{2.25}Te_{12.75} solid solution, the thermal conductivity decreases with increasing temperature approximately as T^{½}. This temperature dependence is typical of a phonon scattering by point defects. The values for the solid solution are lower than for the binary compound because of the mass and volume fluctuations introduced by the substitution of Se atoms for Te atoms. At room temperature the thermal conductivity is 10 mW/cmK, decreasing to a minimum of 6 mW/cmK at 600K.

Using the same information presented above, the minimum thermal conductivity for Re₆Te₁₅ which corresponds to the same material in the amorphous state. For the calculation, the measured speed of sound and an atomic density of 3.52×10²⁸ m⁻³ is used.

At room temperature, the calculated minimum value is 2.3 mW/cmK and the minimum measured value is 10 mW/cmK for the Re₆Se_{2.25}Te_{12.75} solid solution. This seems again to indicate that scattering of the phonons by point defects cannot yield thermal conductivity comparable to an amorphous material.

Re₆Te₁₅ may have low thermal conductivity values because of the heavy masses of the elements forming the compounds as well as the larger number of atoms per unit cell. Experimental results have shown that thermal conductivity is low, significantly lower than for state-of-the-art thermoelectric materials between 300 and 800K. However, there also seems to be room for further reducing the lattice thermal conductivity. In addition, Re₆Te₁₅—based Chevrel phases may have significant voids in the structure.

FIG. 7 illustrates the location of the voids inside the crystal structure. The large spheres represent the atoms that can possibly be inserted in these voids. The radius of the voids may be 2.75 Å and therefore each of the voids is large enough to accommodate a great number of different type of atoms. The filled compositions can be represented by the formula Re₆M₂Te₁₅. Although the possibility of inserting additional atoms in the voids of the Re₆Te₁₅ structure has been suggested in the literature, this has not been done for the purpose of thermoelectric optimization.

Filled Re₆Te₁₅ samples with Ag, Cd and Fe were synthesized. The filling elements were added to the pre-synthesized Re₆Te₁₅ powders and the mixtures were annealed for 5 days at 775K. The powders were then hot-pressed under the same conditions as unfilled Re₆Te₁₅ samples. MPA of the samples filled with Fe and Cd showed a significant amount of secondary phases and no phase corresponding to a filled composition could be detected. For Ag filled samples were essentially composed of several filled compositions Re₆Ag₄te₁₅ with 0.5≦x≦1.14.

Although only a few embodiments have been disclosed in detail above, other modifications are possible.

What is claimed is:

1. A method, comprising:
using a Chevrel phase material as a thermoelectric element.

2. A method as in claim 1, wherein said Chevrel phase material includes filled Chevrel phase materials, which are filled with a metal filling element.

3. A method as in claim 1, wherein said materials are Ternary chalcogenides of formula MₓMo₆X₈, where M is Cu, Ag, Ni or Fe, or rare earth, and X is S, Se or Te.

4. A method as in claim 1, wherein said Chevrel phase material is of the general form (Cu, Cu/Fe, Ti)ₓMo₆Se₈.

5. A method as in claim 3, wherein said Chevrel phase has a cluster valence electron quotient, calculated by adding the valence electrons of M atoms to the valence electrons of the Mo atoms, subtracting the number of electrons required to fill the octets of the chalcogen atoms and dividing by the number of Mo atoms.

6. A method as in claim 2, wherein said Chevrel phase is a rhombohedral Chevrel phase, and said metal filling atoms fill voids in the rhombohedral structure.

7. A method as in claim 1, wherein said Chevrel phase material includes Re₆Te₁₅.

8. A method as in claim 1, further comprising forming Chevrel phase materials by mixing materials which will form a crystal, and annealing said materials to form close to a single phase material.

9. A method as in claim 8, further comprising filling said materials with a filling element which is capable of moving within voids in the crystal material.

10. A method as in claim 9, further comprising controlling a thermal parameter of the material, which thermal parameter measures the ability of the filling element to rattle inside the voids in the crystal material.

11. A method as in claim 1, wherein said using comprises adding additional materials to the Chevrel phase material that scatters phonons.

12. A method as in claim 11, wherein said adding additional materials in its materials that result in a room temperature lattice thermal conductivity value of around 10 mw/cmK.

13. A method as in claim 8, wherein said material is 97 percent single phase material.

14. A method as in claim 11, wherein said additional materials include atoms of Cu, Ni, Fe or Ti.

15. A method as in claim 1, wherein said using comprises using a Chevrel phase material which has a cluster valence electron count between 3.3 and 4.

16. A method as in claim 1, wherein said using comprises using a Chevrel phase material which is a semi conducting Chevrel phase.

17. A thermoelectric material comprising a filled Chevrel phase material, having crystalline material with voids defined between crystalline elements, and metal filling atoms defined within the voids, said metal filling atoms being movable within the voids.

18. A thermoelectric material as in claim 17, wherein said Chevrel phase material is of the general form MₓMo₆X₈, where M is Cu, Ag, Ni or Fe, or rare earth, and X is S, Se or Te.

19. A thermoelectric material as in claim 17, wherein said thermoelectric material includes an Mo₆ octahedron cluster surrounded by 8 chalcogens arranged in a distorted cube.

20. A thermoelectric material as in claim 18, wherein said material is (Cu, Cu/Fe, Ti)ₓMo₆Se₈.

21. A material as in claim 17, wherein said material is semiconducting.

22. A material as in claim 17, wherein said material is CU₄Mo₆Se₈.

23. A material as in claim 17, wherein said material is TiMo₆Se₈.

24. A material as in claim 17, wherein said material is MₓRe₆Te₁₅.

25. A Chevrel phase material formed of substantially single phase, polycrystalline samples of (Cu, Cu/Fe, Ti)ₓMo₆Se₈.

26. A semiconducting ternary Chevrel phase material.

27. A method, comprising:
forming a Chevrel phase crystalline material with a metal filling element rattling in voids.

28. A method as in claim 27, wherein said metal filling element is one of Cu, Fe or Ti.

29. A method as in claim 27, wherein said Chevrel phase material includes Mo therein.

30. A method as in claim 28, wherein said Chevrel phase material has a cluster valence electron count of between 3.3-4.

31. A method as in claim 27, wherein said Chevrel phase material includes units of Mo₆Se₈.

32. A method as in claim 31, wherein said the units are stacked, and stacking of said Mo₆Se₈ units leaves empty channels where additional metal atoms can be inserted, with areas optimized for thermoelectric operation.

33. A material as in claim 17, wherein said material is Cu₂FeMo₆Se₈.
